(19) United States
(12) Patent Application Publication
(10) Pub. No.: US 2025/0253810 A1
(43) Pub. Date: Aug. 7, 2025

(54) Devices and Methods for Non-Linearity Cancellation with Machine Learning Assisted Optimization for Power Amplifiers

(71) Applicant: Mitsubishi Electric Research Laboratories, Inc., Cambridge, MA (US)

(72) Inventors: Koon Hoo Teo, Lexington, MA (US); Shrestha Bansal, Cupertino, CA (US)

(73) Assignee: Mitsubishi Electric Research Laboratories, Inc., Cambridge, MA (US)

(21) Appl. No.: 18/430,116

(22) Filed: Feb. 1, 2024

(51) Int. Cl. H03F 1/32; H03F 1/56; H03F 3/24

(52) U.S. Cl. CPC H03F 1/3241; H03F 1/56; H03F 3/245; H03F 2200/222; H03F 2200/387; H03F 2200/451

(57) ABSTRACT

A signal transmitter for transmitting signals in a radio frequency (RF) domain is provided. The transmitter comprises circuitry configured to receive a source RF signal in the RF domain and produce a pre-distortion RF signal in the RF domain with a phase and a magnitude dependent on a phase and a magnitude of the source RF signal. The circuitry is further configured to combine the source RF signal and the pre-distortion RF signal to produce a combined RF signal and amplify the combined RF signal to produce an amplified RF signal. The circuitry outputs the amplified RF signal through a suitable transmission medium. An extremum seeking controller determines the phase and amplitude of the pre-distortion RF signal based on the phase and amplitude of the source RF signal.

### TECHNICAL FIELD

The present disclosure relates generally to power amplifiers, and more particularly to devices and methods for suppressing performance deterioration in such power amplifiers.

### BACKGROUND

Electronic transmission of signals is an essential process in several real-world applications. Needless to say, along with data processing and storage, data communication is an inherent component of almost all connected devices. Often the signals for transmission are not in transmittable form and require amplification prior to transmission to mitigate the effects of signal interference, decay, and thereby loss of useful data. However, where signals are to be transmitted over long range, pre-transmission amplification may alone not be sufficient to mitigate the aforementioned problems. Instead, repeaters may be required at regular intervals to maintain the power level of the signal under transmission. In this regard, power amplifiers (PAs) form an important part of the transmitter chain by amplifying the power levels of the transmitted signal to ensure high-fidelity signal delivery to the receiver. A radio-frequency power amplifier (RF power amplifier) is an electronic device that increases the power of a radio-frequency signal. RF power amplifiers are also used in the final stage of a radio transmitter, with their output driving the antenna. For example, rapidly emerging fields of 5th generation New Radio (5G-NR) and millimetre-wave (mm-Wave) communication require wideband signal transmission, thus requiring a wideband PA.

However, the performance of such wideband transmitters is affected not only by the PA's in-band non-linearity but also by the out-band higher-order harmonics and spectral regrowth present in the adjacent channel. More importantly, memory effects creating distortion in the output, necessitates a need for methods to overcome these PA impairments. As such, wideband PAs suffer from a deterioration in performance due to in-band harmonics and intermodulation (IMD) components. This leads to severe degradation in the transmitted signal quality which is difficult to mitigate. Some attempts in this regard using digital-predistortion techniques to improve these non-linearities have met with the requirement of extensive modelling of the PA. Also, such digital-predistortion techniques have failed to address the issue of harmonic cancellation.

Accordingly, devices and methods for mitigating PA impairments arising from second harmonic components are needed.

### SUMMARY

Example embodiments described herein are directed towards an improved power amplifier device, a radio frequency (RF) transmitter based on such a power amplifier device and methods for cancelling intermodulation components and harmonics in such power amplifier devices. Some example embodiments provide an efficient machine learning based linearization system which not only reduces IMD components by injecting a predistortion signal in the baseband, but also effectively reduces second harmonic components by injecting an RF signal. In this regard, some example embodiments provide an extremum seeking algorithm for determining the phase and amplitude of the injected signal, which reduces the convergence time as compared to linear search.

Some example embodiments are based on the realization that a single-ended design of a power amplifier (PA) may be easier to test and can be easily interfaced with widely used single-ended antenna, and hence typical PA designs cascade multiple single-ended amplification stages. Some embodiments are also based on a recognition that differential designs, on the other hand, provide lower feedback from the ground node thereby lowering the feedback due to bond wires, and also enhance the transmitter voltage gain by utilizing the full range of the upconverter output. Such differential designs also have the capability to cancel even order harmonics that might translate into the in-band frequencies for wideband or multi-band power amplifiers. Some example embodiments recognize that such differential designs, however, need a balun to interface with the single-ended antenna which in turn introduces additional losses limiting the enhancement of voltage gain.

Doherty power amplifiers (DPAs), that are typically used to amplify high peak to average power (PAPR) ratio signals, comprise of i.) a main amplifier operating in a class-A configuration and used to amplify the input signal and ii.) an additional peaking amplifier or auxiliary amplifier in class-C configuration, which is used when the gain of the main amplifier begins to saturate, and the output begins to compress. Some embodiments realize that such a configuration helps the output of the PA to be relatively linear even at high input power levels. However, it is a realization of some example embodiments that even the DPAs suffer from several performance and design impairments. Particularly, the design of a DPA is inherently complex due to the quarter wave modulators at the input of the auxiliary amplifier and the output of the main amplifier. Also, DPAs are usually designed in single-ended configurations to avoid further design complications and have strong non-linear behaviour which must be corrected by using digital techniques.

It is a realisation of some embodiments that another approach called digital pre-distortion (DPD), which is a baseband linearization technique widely used to linearize the PA characteristics by adding an inverse of the PA non-linearity to the input of PA, can effectively model non-linearities with memory effects. Although DPD is effective in linearizing in-band and near-band distortions such as intermodulation (IMD) components, it is a realization of several embodiments that it requires elaborate modelling of the PA making it highly complex. Moreover, even though DPD significantly improves the transmitted signal characteristics within the band of transmission, wideband issues such as the presence of harmonics still remain unaddressed.

Some example embodiments are based on the realization that one way to cancel the intermodulation (IMD) components may be by injecting a pre-distortion signal (PDS) at intermodulation frequencies. This method is less complex and computationally more efficient than DPD since it does not require modelling of the PA. Some embodiments, through experimentation, realized that this scheme effectively suppresses the IMD components and leads to an improved PA performance. Further, this scheme reduces IMD components effectively for both two-tone signals and a carrier band signal. However, some embodiments recognize that this method, although shows promising performance in standalone PA simulations, does not consider the peripheral circuitry of the PA such as transmission lines, matching circuitry, etc.

Some example embodiments also realize that wideband PAs with bandwidths greater than the central passband frequency additionally suffer with a deterioration in performance due to second order harmonics of the lower passband frequencies translating in the upper spectrum side of the passband. Further, multi-band PAs also suffer due to second harmonic components translating in in-band or subsequent bands. This leads to a higher harmonic distortion figure significantly affecting the signal quality. For example, a wideband PA may have a bandwidth 5 GHz, and for an input signal at f₀ of 2 GHz, wherein f₀ is a fundamental frequency, if such a wideband PA is tasked to amplify the signal with frequency f₀, the second-order harmonics would appear within its bandwidth thereby deteriorating the fundamental signal. Notably, in view of such impairments the advance of emerging 5G-NR and mm-Wave communication poses new challenges in the PA industry.

Some example embodiments are based on the understanding that second-order harmonics can be suppressed with a distortion signal injected into the amplified signal before its amplification. Such a pre-distortion is different from other distortions aimed to address other deficiencies of PAs, such as intermodulation (IMD) components, etc., due to the nature of the higher-order harmonics. For example, some embodiments are based on the understanding that the criteria for the selection of parameters of the pre-distortion signal should be the phase and magnitude of the amplified signal that in turn governs the phase and the magnitude of the pre-distortion signal.

For example, some embodiments are based on recognizing that it is possible to cancel the intermodulation components by injecting an inverted pre-distortion signal at intermodulation frequencies. However, some embodiments also realize that if the pre-distortion signal is injected on baseband frequencies, for a realistic PA, the phase injection scheme fails to work and in turn leads to an ineffective reduction of third-order intermodulation (IM3) components. After numerous simulations and experiments necessitating the construction of a dedicated testing workbench, the embodiments realized that such a deficiency comes from at least two problems specific to harmonic suppression.

The first problem comes from the effects of the input and output matching network on the harmonic suppression. In real-case scenarios, the input to the PA from the signal source and output from the PA to the measurement instrument is routed via transmission lines which introduce a frequency and power-dependent phase shift to the input signal. As a result, for generic PAs, a simple 180° phase shift (out-of-phase cancellation) doesn't offer the best IM3 reduction, thereby necessitating a need for a novel methodology to determine the optimum phases of the additional injected tones also called pre-distortion signal (PDS).

The second problem comes from the harmonics of the pre-distortion signal itself. By injecting the pre-distortion signal in the baseband domain, after modulation (up-conversion to RF domain), the two additional injected tones also create harmonics which further deteriorate the amplified signal along with adding further complications due to the frequency translation circuitry such as a mixer.

In order to mitigate the aforementioned shortcomings of classical solutions, example embodiments described herein provide an improved architecture of transmitters for transmitting amplified signals. Some example embodiments provide approaches focused at cancelling even harmonics introduced in the transmission signals due to inherent drawbacks associated with power amplifiers that amplify such signals prior to transmission. It is an object of some embodiments to provide an extremum seeking controller and method for cancelling intermodulation components and second harmonic components through injection of additional signal tones, without the need of computationally expensive modelling procedure. Some example embodiments utilize extremum seeking algorithms to determine the phase and amplitude of the injected signal, which reduces the convergence time as compared to linear search.

In order to achieve the aforementioned objectives and improvements, some example embodiments provide a transmitter device, a signal transmission method, and an extremum seeking controller for generating amplitude and phase of an injection signal for the transmitter device.

Some example embodiments provide a transmitter for transmitting signals in a radio frequency (RF) domain. The transmitter comprises circuitry configured to receive a source RF signal in the RF domain and produce a pre-distortion RF signal in the RF domain with a phase and a magnitude dependent on a phase and a magnitude of the source RF signal. The circuitry is further configured to combine the source RF signal and the pre-distortion RF signal to produce a combined RF signal and amplify the combined RF signal to produce an amplified RF signal. The circuitry outputs the amplified RF signal through a suitable transmission medium.

According to some example embodiments, the circuitry is further configured to detect one or more second harmonics of an n^{th} instance of the source RF signal from the amplified RF signal and adjust the phase and the magnitude of an (n+1)^{th} instance of the pre-distortion RF signal based on the detected one or more second harmonics.

In yet some other embodiments a signal transmission method is provided. The method comprises receiving a source radio frequency (RF) signal in an RF domain and producing a pre-distortion RF signal in the RF domain with a phase and a magnitude dependent on a phase and a magnitude of the source RF signal. The method also comprises combining the source RF signal and the pre-distortion RF signal to produce a combined RF signal and amplifying the combined RF signal to produce an amplified RF signal. The method further comprises outputting the amplified RF signal through a suitable transmission medium.

In yet some other embodiments an extremum seeking controller (ESC) for determining optimum values of amplitude and phase of an injection signal is provided. The injection signal is added as an additional input to a signal transmitter to cancel one or more of harmonics or intermodulation components in an output radio frequency (RF) signal of the signal transmitter. The ESC is communicatively coupled with the signal transmitter. The ESC comprises an input interface configured to receive the output RF signal of the signal transmitter and an objective function generated from the output RF signal. The ESC also comprises a high pass filter, a multiplier circuit, an accumulator circuit, an amplifier, a demodulator, and an output interface. The high pass filter is configured to filter a non-alternating component of the output RF signal to produce a filtered output. The multiplier circuit is configured to multiply the filtered output with a sinusoidal input to produce a demodulated signal. The demodulated signal comprises information indicating a gradient of the objective function. The accumulator circuit is configured to recursively add the demodulated signal to move one or more parameters of the output RF signal in a direction of the gradient of the objective function. The amplifier is configured to add an integrator gain to the demodulated signal in each iteration of the recursive addition to increase convergence of the one or more parameters to reference values. The demodulator is configured to add the sinusoidal input to an output of the accumulator circuit to create a disturbance in values of settled system parameters. The output interface is configured to output the optimum values of the amplitude and phase of the injection signal, based on the settled system parameters with the disturbed values.

### BRIEF DESCRIPTION OF THE DRAWINGS

The presently disclosed embodiments will be further explained with reference to the following drawings. The drawings shown are not necessarily to scale, with emphasis instead generally being placed upon illustrating the principles of the presently disclosed embodiments.

FIG. 1A illustrates schematics of harmonic generation in a wideband transmitter that utilizes power amplifiers, according to some example embodiments;

FIG. 1B illustrates an example of wideband PA output with second harmonic in the passband;

FIG. 1C illustrates an example of wideband PA output with second harmonic outside the passband;

FIG. 1D illustrates a plot showing IM3 reduction vs phase of injected PDS tones, according to some example embodiments;

FIG. 2A illustrates an architecture of an RF signal transmitter utilizing an extremum seeking controller for high order harmonic cancellation, according to some example embodiments;

FIG. 2B illustrates schematics of extremum seeking control by the extremum seeking controller of FIG. 2A for achieving harmonic cancellation in a wideband power amplifier, according to some example embodiments;

FIG. 2C illustrates the extremum seeking method implemented by the extremum seeking controller of FIG. 2A and FIG. 2B, according to some example embodiments;

FIG. 3A shows an input signal with injected pre-distortion at HD2 frequency, according to some example embodiments;

FIG. 3B shows the output signal spectrum with two opposite phased components at HD2 frequency, according to some example embodiments;

FIG. 3C shows the final output spectrum with HD2 suppression after optimization, according to some example embodiments;

FIG. 4 illustrates a plot depicting convergence of the extremum seeking controller of FIG. 2A and FIG. 2B to a maximum value, according to some example embodiments; and

FIG. 5 illustrates the output spectrum of a multi-input Doherty power amplifier before and after second harmonic cancellation, according to some example embodiments.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

The following description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like-reference numbers and designations in the various drawings may indicate like elements.

Power amplifiers (PAs) form an important part of the transmitter chain by amplifying the power levels of the transmitted signal to ensure high-fidelity signal delivery to the receiver. Rapidly emerging 5G-NR and mm-Wave communication requires wideband signal transmission, thus requiring a wideband PA. Radio frequency PAs are non-linear systems due to several reasons. The non-linearity of such PAs causes impairments in the performance of the PA and manifests mainly in terms of two terms-intermodulation (IMD) components and harmonics of the source/input signal.

Intermodulation is a type of signal distortion which occurs when at least two different frequencies are presented to a nonlinear system such as a power amplifier (PA). When a broadband signal is sent into a component with nonlinear impedance, harmonic generation and frequency mixing occur simultaneously which creates additional peaks in the signal's power spectrum. These generated peaks are mathematically related to the input signal's power spectrum, and the additional peaks in the frequency domain produce a distorted signal in the time domain. Intermodulation can cause two types of distortions, i.e., in-band and out-of-band distortions. The former is a result of changing the amplitude and phase of the fundamental frequency signal and can increase the bit error rate of the transmitted signal. Whereas the latter, also known as spectral re-growth, presents new frequency components that are formed outside the frequency band of interest. Some of these components, e.g., the even-order intermodulation products and harmonic products are usually a bit far from the carrier frequency and require additional bulky filters to remove them which increases the complexity at the receiver circuit. Other components, i.e., the odd-order intermodulation products lie close to the fundamental signal and manifest in a harmful way that increases adjacent channel interference. Therefore, the performance of such wideband transmitters is affected not only by the PA's in-band non-linearity but also by the out-band higher-order harmonics and spectral regrowth present in the adjacent channel. More importantly, memory effects creating distortion in the output, necessitates a need for methods to overcome these PA impairments.

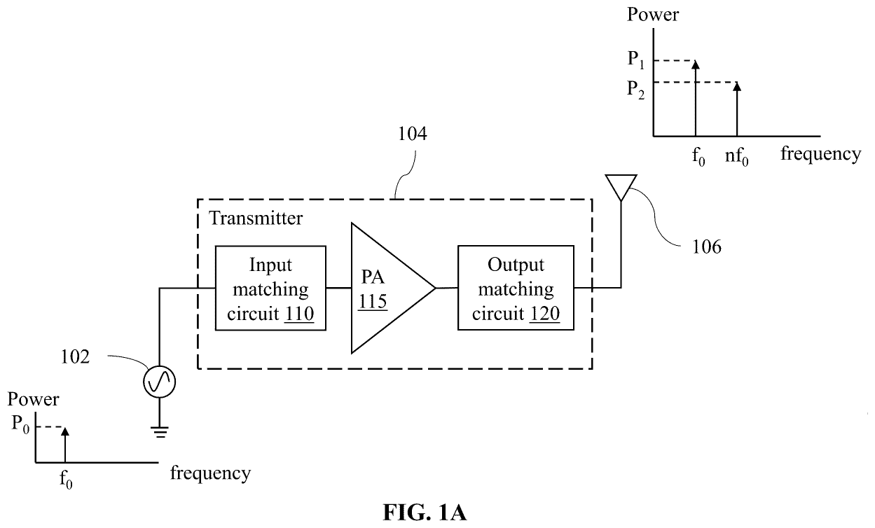

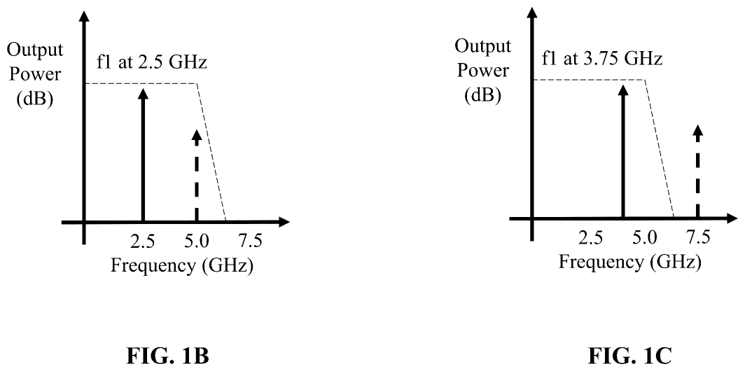

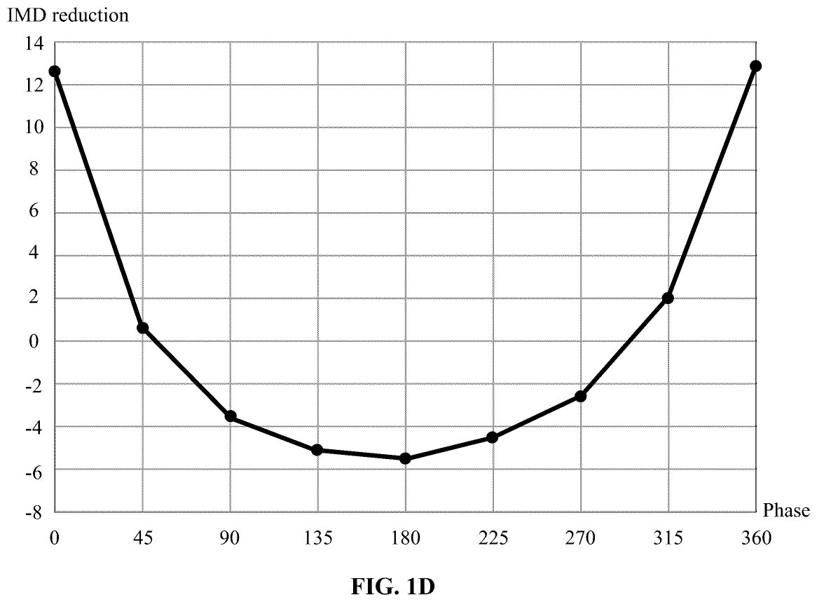

FIG. 1A illustrates schematics of harmonic generation in a wideband transmitter that utilizes power amplifiers, according to some example embodiments. An input signal 102 for transmission by the transmitter 104 is fed to an input matching circuit 110 to perform pre-transmission matching and to avoid transmitter reflection effects. The input matched signal is then amplified by a power amplifier 115 which provides an amplified output. The output matching circuit 120 provides an output impedance suitable for transferring the amplified output from the power amplifier 115 to one or more antennas 106 for transmission. Due to non-linearity of the power amplifier 115, the input signal 106 with a power level P₀ at fundamental frequency f₀ manifests into two or more signal components with power levels P₁ at frequency f₀ and P₂ at frequency nf₀ in the transmitter output. While the component with power level P₁ at frequency f₀ corresponds to the amplification of the input signal, the component with power level P₂ at frequency nf₀ corresponds to the additional harmonics of the input signal.

Since the wideband power amplifiers have a wide bandwidth, the output signal is marred by the detrimental effects of the harmonics (even and odd), which in turn complicates the applicability of such amplifiers. For example, wideband PAs with bandwidths greater than the central passband frequency additionally suffer with a deterioration in performance due to second order harmonics of the lower passband frequencies translating in the upper spectrum side of the passband. Further, multi-band PAs also suffer due to second harmonic components translating in subsequent bands. This leads to a higher harmonic distortion figure significantly deteriorating the signal quality.

In high-bandwidth, multi-band PAs, second order harmonics appear in-band, significantly reducing the non-linearity of the amplifier as shown in FIG. 1B and FIG. 1C. Particularly, FIG. 1B illustrates an example of wideband PA output with second harmonic in the passband while FIG. 1C illustrates an example of wideband PA output with second harmonic outside the passband. Referring to FIG. 1B, the amplified output is shown as the solid arrow at frequency of 2.5 GHz while the second harmonic of the input signal is shown as the dashed arrow at frequency of 5 GHz which is inside the passband (shown as thin dashed line). Similarly, for FIG. 1C, the amplified output is shown as the solid arrow at frequency of 3.75 GHz while the second harmonic of the input signal is shown as the dashed arrow at frequency of 7.5 GHz which is outside the passband (shown as thin dashed line).

To achieve second harmonic cancellation, an additional term needs to be injected as an input to the PA. A negative sign implies that a 180° out of phase component needs to be injected at second harmonic frequency. However, through experimentations, some example embodiments realized that for a realistic PA, such an injection scheme fails to work and in turn leads to an enhancement of intermodulation (IMD) components. Sweeping the phase of the injected additional frequency components, also called predistortion signal (PDS) and observing the IMD reduction at each phase step gives a plot as shown in FIG. 1D where the horizontal axis represents the phase of the injected PDS tones, and the vertical axis represents the corresponding IMD reduction. Some embodiments realized that maximum reduction was achieved at 0°/360° instead of a 180° phase shift, while at 180° phase shift, PDS added to the IMD components to make the PA more non-linear. This is observed primarily because the PA is simulated standalone while not considering the effects of the input and output matching network. In real world scenarios, the input to the PA from the signal source and output from the PA to the measurement instrument is routed via transmission lines which introduce a frequency and power dependent phase-shift to the input signal. As a result, for generic PAs, a 180° phase shift (out-of-phase injection) doesn't offer the best IMD reduction, thereby necessitating the need for a novel methodology to determine the optimum phases of PDS tones.

For real world applications, in order to achieve second harmonic cancellation, an additional term needs to be injected in the system. However, due to the peripheral circuitry of the PA, a 180° injection is not desirable, and the phase of injection needs to be modified. While baseband injection is one approach in this regard especially in transceiver chains where the input signal is usually generated in baseband domain, it leads to other non-linearities including a larger DC component since the system doesn't behave as a single tone system anymore. This larger DC component requires elimination by a high-pass filter (HPF), but that is counterproductive because the main motivation of baseband injection was to eliminate bulky filter banks. Accordingly, some example embodiments are based on the realization that the injection of the PDS tones should be in RF domain. Using RF injection, some embodiments eliminate the non-linearities introduced by the mixer, therefore reducing the intermodulation components arising due to the up conversion of the injected signal. RF injection also simplifies the system development and is particularly useful for wideband and multi-band PAs because it reduces the complexity by eliminating the need of having tunable filter banks for specific frequency ranges.

Also, certain wideband PA architectures utilize multiple narrow bands to cater to a specific input frequency range and may use multiple narrow bands to create a wideband spectrum. This increases the number of input frequencies and consequently makes the harmonic cancellation a difficult task since second harmonics from multiple individual bands might overlap with other bands. This in turn increases the number of variables to be optimized.

Towards this end, some example embodiments utilize extremum seeking (ES) algorithms to find the optimum values of phase and amplitude of the injection signal. Some embodiments also model the PA along with its peripheral circuitry to determine the exact behaviour of the amplifier. Some embodiments generate such a PA model using a memoryless nonlinearity, memory polynomial (MP) or a memory polynomial with cross terms model. Digital pre-distortion techniques require precise modelling of the PA and add an inverse non-linear component of the PA behaviour to cancel out the non-linearities. One approach in this regard characterizes the PA behaviour as a Volterra series model and assumes PA to exhibit memoryless non-linearity behaviour. However, the non-linear behaviour does in fact have a memory component and therefore some approaches utilize modified Volterra series models such as memory polynomial (MP) and generalized memory polynomial (GMP) models for in-band non-linearity reduction. MP model estimates the PA output y_{MP}(n) given by:

$${y}_{MP} ( n ) = {\sum }_{k = 1}^{K} {\sum }_{m = 0}^{M - 1} {a}_{km} x ( n - m ) {\vert x ( n - m ) \vert}^{k} \qquad ( 1 )$$

and requires evaluation of multiple coefficients αₖₘ, where k represents the envelope order and m represents the memory depth. However, all such approaches fail to consider the PA peripheral circuitry for this estimation to limit further complexities.

To accurately model the PA for both in-band and out-of-band non-linearity reduction, the amplifier along with its peripheral circuitry needs to be characterized to determine its exact behaviour. This is done by connecting the PA in a closed loop with MATLAB which provides a test-input pattern and subsequently observes the amplified output. Using this input-output data set, a PA model is generated using a memoryless nonlinearity, memory polynomial (MP) or a memory polynomial with cross terms model. Using this methodology, the amplitude-to-amplitude (AM/AM) and amplitude-to-phase (AM/PM) distortion characteristics of the PA may be obtained. According to some embodiments, the modelling procedure can also be performed without working on the hardware bench with a PA in the loop but using pre-recorded input-output data of the PA either through measurements done previously or done through simulations in circuit envelope simulators such as Keysight ADS.

Some embodiments use the model thus created to design a closed-loop system and obtain a cost function using the PA's second harmonic component. The task for the ES optimizer is then to minimize the value of the second harmonic component.

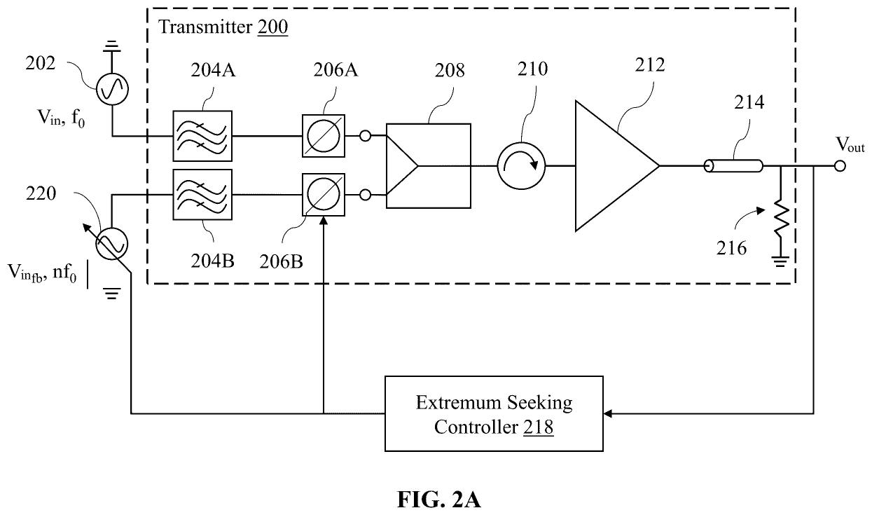

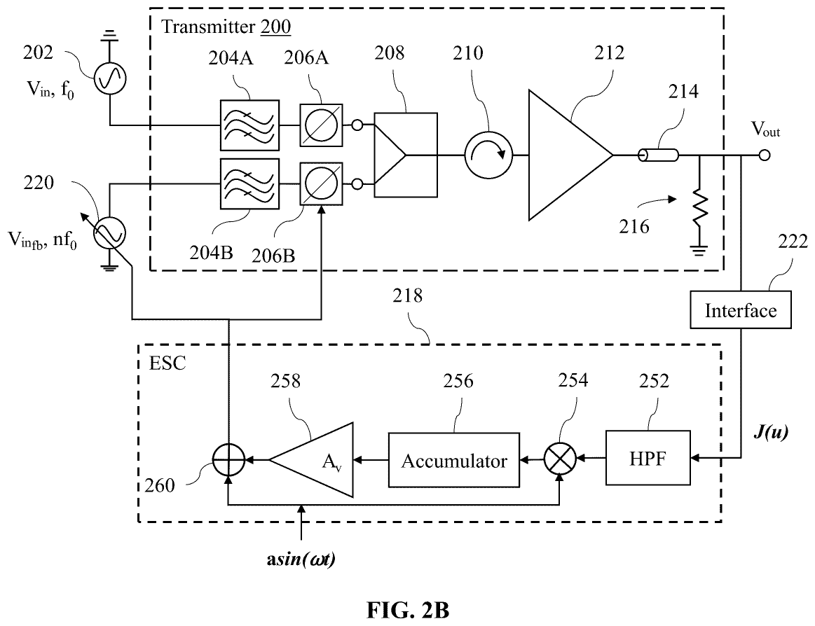

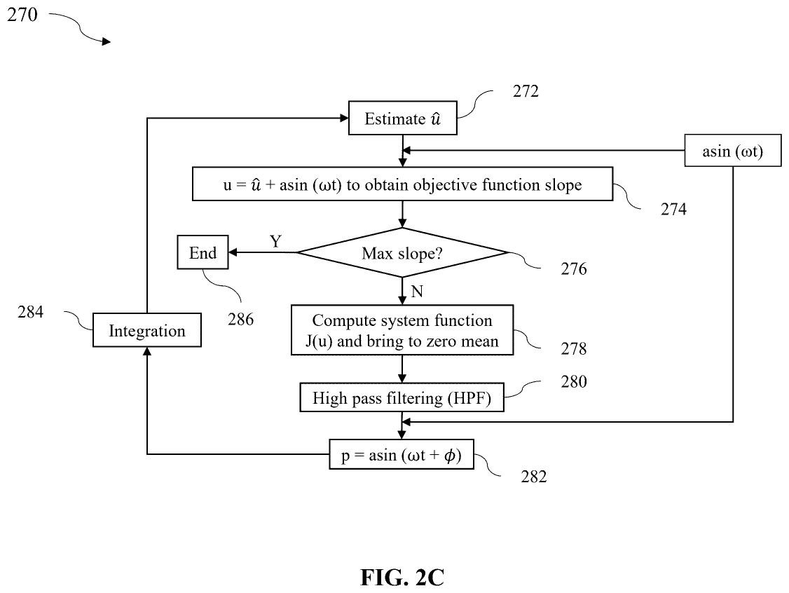

FIG. 2A illustrates an architecture of an RF signal transmitter utilizing an extremum seeking controller for high order harmonic cancellation, according to some example embodiments. The transmitter 200 is configured to transmit a source RF signal 202 with amplitude Vᵢₙ at frequency f₀. The source RF signal may be a high frequency signal which behaves as the carrier for the baseband signals that carry the information from one point to another. RF signals can be anything, a single tone signal at high frequency or a group of multiple tones. An injected signal 220 or a pre-distortion input is also provided as an input to the transmitter for cancelling second and/or higher order harmonics of the source RF signal 202. According to some example embodiments, the amplitude and phase of the injected signal 220 is tunable and is dependent on the amplitude and phase, respectively, of the source RF signal 202.

The transmitter 200 comprises a source input matching circuit realized with a bandpass filter (BPF) 204A and a phase shifter 206A to remove outliers and compensate for signal processing and filtering delays in the transmitter. The BPF 204A allows signals in a particular frequency band to pass through it and block signals outside of that block. The phase shifter 206A modifies the phase of the filtered source RF signal. For example, if the filtered source RF signal is represented as x=a sin(ωt), after phase shifting the output of the phase shifter 206A becomes y=a sin(ωt+ϕ) where ϕ is the added phase delay.

The transmitter 200 also comprises an injected input matching circuit realized with a bandpass filter (BPF) 204B and a phase shifter 206B to remove outliers and compensate for signal processing and filtering delays in the transmitter. Similar to the BPF 204A, the BPF 204B allows signals in a particular frequency band to pass through it and block signals outside of that block. Similar to the phase shifter 206A, the phase shifter 206B modifies the phase of the filtered source RF signal. As is shown in FIG. 2A, the phase shifter 206B operates on the injected signal to shift its phase based on optimized parameters provided by an extremum seeking controller 218, which is described in detail later in this disclosure.

The transmitter 200 also comprises a power combiner circuit 208 realized with a signal mixer to combine signals input to it in frequency domain. For example, as shown in FIG. 2A, the power combiner circuit 208 adds the input matched source RF signal and the input matched injected signal in frequency domain to produce a combined signal. A circulator 210 ensures that signal entering from the input port is directly passed on to the output port of the transmitter i.e. it minimizes RF signal reflections and ensures output matching in the transmitter 200. The transmitter 200 further comprises an RF power amplifier 212 for amplifying the combined signal. According to some embodiments, the PA 212 may be a wideband power amplifier. According to some embodiments, the PA 212 may be a multi-input amplifier. The transmitter 200 also comprises an output matching circuit realized with a transmission line 214 and a resistor 216 providing an output impedance for the PA 212. For example, together the transmission line 214 and a resistor 216 may provide a 50 Ohm output impedance for subsequent blocks.

As discussed previously, due to the non-linear characteristics of the PA 212, the output signal Vout includes second and/or higher order harmonics of the source RF signal 202 and IMD components. To cancel these harmonics and IMD components, the transmitter 200 may be coupled to an extremum seeking controller (ESC) 218 that iteratively determines optimized phase and amplitude of the injected signal 220 which in turn contribute to reduction, suppression or cancellation of the harmonics and IMD components. The injected signal 220 is provided to the transmitter 200 as a feedback signal with amplitude Vᵢₙ_{_{fb}}, and frequency nf₀ where n is a non-negative integer, as shown in FIG. 2A. One or more parameters such as amplitude and phase of the injected signal may be tunable based on one or more optimized parameters output by the ESC 218 which is described in detail next. Using RF injection, the non-linearities introduced by the mixer/power combiner are eliminated in a multi-input PA, therefore reducing the intermodulation components arising due to the up conversion of the injected signal. RF injection also simplifies the system development and is particularly useful for wideband and multi-band PAs because it reduces the complexity by eliminating the need of having tunable filter banks for specific frequency ranges.

For achieving IMD cancellation, some embodiments utilize linear search techniques to determine the phase of the injected signal 220. For a non-linear PA such as the amplifier 212, Vₒᵤₜ=k₀+k₁Vᵢₙ+k₂Vᵢₙ²+k₃Vᵢₙ³+ . . . , ignoring terms with order four and more. If the input power of the PA is swept, and a corresponding output plot is observed, the values of constant coefficients k₀, k₁, k₂, k₃ can be calculated in MATLAB using linear regression and since for a particular PA these coefficients remain the same, this estimation needs to be performed only once. A simplified expression for Vₒᵤₜ may then obtained by assuming Vᵢₙ to be a two-tone signal given by Vᵢₙ=a₁ sin(ω₁t)+a₂ sin(ω₂t), where a₁ and a₂ are the amplitudes of the two input tones at frequencies ω₁ and ω₂. By substituting this two-tone expression of Vᵢₙ and the coefficients calculated through linear regression, a new equation of Vₒᵤₜ is obtained. The expression thus obtained for Vₒᵤₜ contains information about fundamental tones, intermodulation components and higher order harmonic components.

Additional frequency components, also called pre-distortion signals (PDS) at IMD frequencies f₀±2Δf with a certain phase shift are then injected based on the amplitude obtained from the previous calculation. According to some example embodiments, in order to achieve IMD cancellation through pre-distortion signal injection, only phase optimization may be required and therefore the phase of injected signal 220 may be determined using linear search to reduce the computational complexity. The required phase shift may then be chosen based on the determined phase of the injected signal 220. This process can also be used for IMD cancellation of a wideband carrier by utilizing multiple closely spaced PDS tones to enhance the adjacent channel power ratio (ACPR).

FIG. 2B illustrates schematics of extremum seeking control by the ESC 218 for achieving harmonic cancellation in a wideband power amplifier, according to some example embodiments. As an example, some wideband PAs utilize multiple narrow bands to cater to a specific input frequency range and might use multiple narrow bands to create a wideband spectrum. This increases the number of input frequencies and consequently makes the harmonic cancellation a difficult task since second harmonics from multiple individual bands might overlap with other bands. This in turn increases the number of variables to be optimized from two to four or even more for such PAs. To address this challenge, an extremum seeking controller such as the ESC 218 may be used to find the optimum values of phase and amplitude of the injection signal 220. ES controller is an effective solution that not only converges to the solution at a faster rate but can also handle time varying PA non-linearities such as temperature variations effectively.

The ES control provided by the ESC leads to an efficient linearization scheme which reduces the convergence time as compared to linear search for converging to optimum parameters for a given objective function. Extremum Seeking(ES) control is a robust closed-loop control methodology with an ability to track system variations and maintain the objective function at its optimal point.

Referring to FIG. 2B, the ESC 218 may be coupled to the transmitter 200 through a suitable interfacing computer 222. The interfacing computer 222 may process the output of the transmitter 200 to detect one or more of harmonic or intermodulation components in the output signal. A suitable cost function J(u) may accordingly be defined by the interfacing computer 222 and provided to the ESC 218 to optimize the cost function. According to some example embodiments, the interfacing computer 222 may be a part of the ESC 218 itself. The architecture of the ESC 218 comprises a high pass filter 252, a multiplier circuit 254, an accumulator circuit 256, an amplifier 258, and a demodulator 260. Additionally, according to some example embodiments, the ESC 218 may comprise one or more input interfaces configured to receive data and one or more output interfaces configured to output data. According to some example embodiments, the components of the ESC 218 may be realized in hardware, software or a combination of both. In this regard, although not shown for the sake of brevity, the ESC 218 may additionally include a memory for storing data, computer programs and software and one or more processors for executing the programs and software to implement an extremum seeking algorithm. The one or more processors may interface with one or more other components of the ESC 218 to implement one or more modules of the extremum seeking algorithm.

The ESC 218 estimates the optimum values of one or more system parameters denoted as û and then adds a sinusoidal perturbation a sin(ωt) to it which allows it to probe the slope of the objective function J(u) at that particular estimated value. As a result, the system input is updated to u=û+a sin(ωt). This value of u is then used as the new optimum value and is used to compute the system response J(u). This system response does not have a zero mean and to bring it to zero mean, it is then passed through a low cut-off frequency high-pass filter 252. A multiplier circuit 254 multiplies the high pass filtered output ρ with the same sinusoidal input a sin(ωt) but phase shifted to account for the system delay, (i.e., with a sin(ωt+ϕ)) to obtain a demodulated signal which contains the information about the sign of the slope of objective function. An accumulator circuit 256 accumulates the demodulated signal continuously over time to yield a new set of optimum parameters û. In this regard, an integrator gain is introduced by an amplifier 258 to speed up the convergence of the controller to the optimum value of objective function. The demodulator 260 adds the sinusoidal perturbation a sin(ωt) to the optimum parameters. The new set of optimum parameters is used to set the amplitude and phase of the injected signal 220. Since the parameters are determined with the objective of minimizing the harmonic component in the output signal, the injected signal when combined with the source RF signal in the RF domain effectively cancels out the harmonic components.

One example of the signal modelling for achieving second harmonic cancellation is described next. For the non-linear power amplifier with a sinusoidal input signal x(t)=Acos(ωt), the output may be defined as:

$$y ( t ) = {α}_{1} Acos ( ω t ) + {α}_{2} {A}^{2} {cos}^{2} ( ω t ) + {α}_{3} {A}^{3} {cos}^{3} ( ω t ) + ⋯ \qquad ( 2 )$$

$$y ( t ) = {α}_{1} Acos ( ω t ) + \frac{{α}_{2} {A}^{2}}{2} ( 1 + cos ( 2 ω t ) ) + \frac{{α}_{3} {A}^{3}}{4} ( 3 cos ( ω t ) + cos ( 3 ω t ) ) + ⋯ \qquad ( 3 )$$

Ignoring harmonic terms higher than third order since for some applications, the region of interest may be limited to second order harmonics, the output may be simply rewritten as:

$$y ( t ) = {α}_{1} Acos ( ω t ) + \frac{{α}_{2} {A}^{2}}{2} ( 1 + cos ( 2 ω t ) ) \qquad ( 4 )$$

For the optimization of second harmonic component, the objective function is determined as:

$$f ( α , u ) = {P}_{{f}_{0}} ( dB ) - {P}_{2 {f}_{0}} ( dB ) \qquad ( 5 )$$

Thus, on a logarithmic scale, the objective function for second harmonic cancellation translates to a ratio of the power of source signal 202 to the power of second harmonic component. The objective function for higher order harmonic cancellation may be defined suitably through experimentation.

FIG. 2C illustrates the extremum seeking method 270 implemented by the ESC 218 of FIG. 2A and FIG. 2B, according to some example embodiments. The method 270 comprises estimating 272 one or more parameters û of the output signal from the transmitter 200 of FIGS. 2A and 2B. A small signal sinusoidal perturbation a sin(ωt) is added to the estimated parameters to obtain 274 value of the parameter u=û+a sin(ωt) which allows it to probe the slope of the objective function at that particular estimated value. The slope of the objective function is determined as a part of step 274 and is checked 276 for a maximum. If the determined slope is equal to the maximum slope, it corresponds to convergence of the estimated values with optimum or reference values and in such a case the algorithm terminates at 286. However, for practical scenarios, when the ES method is initialized, the determined slope of the objective function is not equal to the maximum slope and in such a case, the method 270 proceeds to compute 278 the system function J(u) to bring it to zero mean. The system function has a non-alternating (DC) component at a certain frequency and an alternating component at some other frequency. The method 270 utilizes high pass filtering 280 to filter out the non-alternating component and the filtered output is modulated by a multiplier with the same sinusoidal perturbation a sin(ωt) utilized at step 274 but phase shifted to account for the system delay, (i.e., with a sin(ωt+ϕ)) to obtain 282 a demodulated signal (p=a sin(ωt+ϕ)) which contains the information about the sign of the slope of objective function. The demodulated signal is accumulated as a part of an integration/accumulation step 284 continuously over time to yield a new set of optimum parameters û. In this regard, an integrator gain is introduced to speed up the convergence of the controller to the optimum value of objective function. The new set of optimum parameters is used to set the amplitude and phase of the injected signal 220.

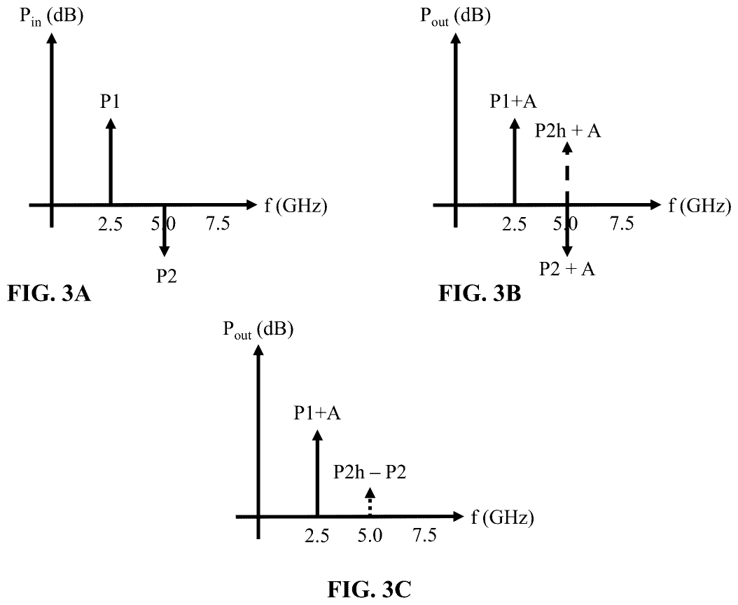

FIG. 3A shows an input signal with injected pre-distortion at HD2 frequency and FIG. 3B illustrates the output signal spectrum with two opposite phased components at HD2 frequency, according to some example embodiments. FIG. 3C shows the final output spectrum with HD2 suppression after optimization, according to some example embodiments. Referring to FIG. 3A, the source signal with a power P1 at frequency 2.5 GHz is fed to the transmitter. The corresponding output signal has a spectrum with a component P1+A at frequency 2.5 GHz, where A is additional power due to amplification and a second harmonic component P2h+A at frequency 5 GHz. In order to cancel this second harmonic, the ESC 218 of FIGS. 2A and 2B determines the amplitude and phase of the injected signal which has a component P2 at 5 GHz. Thus, the input spectrum of the transmitter includes the source signal 202 and the injected signal 220 shown as components P1 and P2 in FIG. 3A. The injected signal causes suppression of the second harmonic P2h+A (shown in thick dash in FIG. 3B) of the source signal and the suppressed harmonic component is shown as the component P2h-P2 in FIG. 3B.

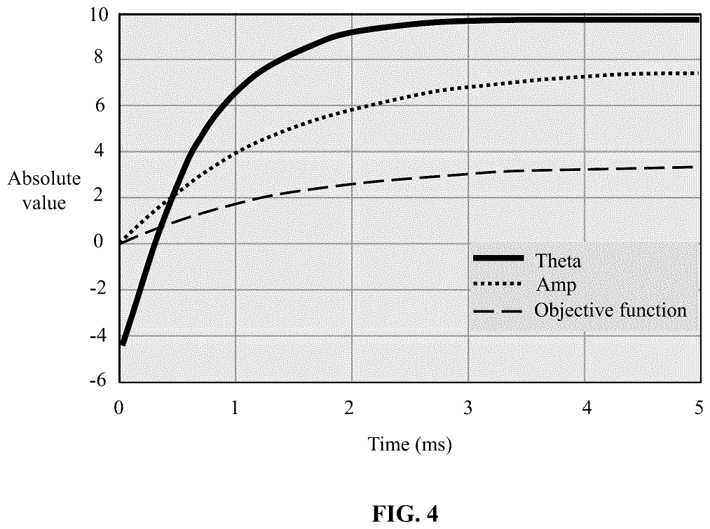

One example use case to demonstrate the IMD cancellation and harmonic cancellation for a chosen non-linear power amplifier is described next. IMD cancellation through pre-distortion signal injection only requires phase optimization and therefore the phase of injection is determined using linear search to reduce the computational complexity. As shown in FIG. 4, the mean squared power of the amplified output signal at 100 kHz and −100 kHz is 5.43 dBm, while the IMD tones at 2f₂-f₁ and 2f₁-f₂ frequencies of 300 kHz and −300 kHz is-16.14 dBm prior to IMD cancellation (shown as dashed curve) for a selected non-linear power amplifier model with peripheral circuitry. By using the ES methodology described with reference to FIGS. 2B and 2C, the amplitude of PSD tones to be injected at the input is determined and injected with an initial phase of 0°. Subsequently, this phase is linearly swept from 0° to 360° with a 5° increment for accurate estimation of the phase of injection. For the chosen amplifier, it is observed that maximum suppression of IMD tones is observed at 135° phase, yielding the spectrum shown in FIG. 4 (shown as thick continuous curve) with the IMD components at −39.41 dBm showing a 23.27 dB mean squared power reduction.

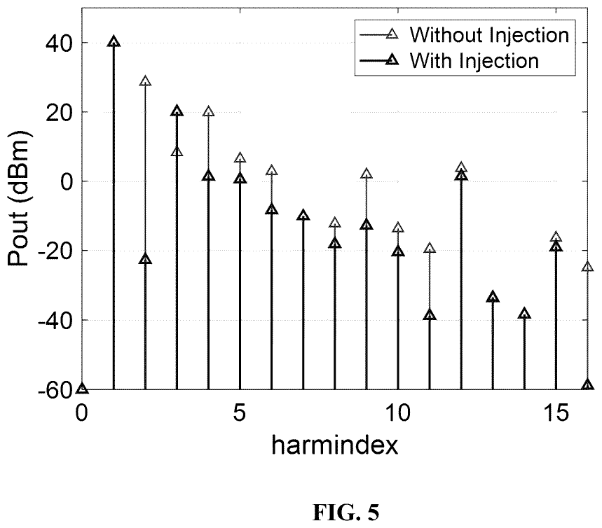

Harmonic cancellation scheme is more complex than IMD cancellation and requires at least two parameters to be swept at the same time to achieve desirable spectrum. Using extremum seeking controller the optimum values of amplitude and phase of the injection signal are determined. ES controller is perturbed using a 1 kHz sinusoidal signal with a low amplitude of 0.1. The gain Aᵥ of the integrator is set as 20 to speed up the rate of convergence. As shown in FIG. 4, the ES controller maximizes the objective function defined by (5) to reduce the second harmonic component. Output spectrum of a modelled Doherty PA with the fundamental frequency component at 3.8 GHz is shown in FIG. 5. It is observed that the power of the second harmonic component goes down from 28.605 dBm to −22.726 dBm, resulting in a 51.331 dB reduction at an injection angle of 164°. The convergence of the objective function is achieved in around 4 seconds, depicting real-time optimization. The ES controller not only minimizes the second harmonic component but also maintains the ratio of fundamental component to the second harmonic component power at maximum value during the normal operation of the Doherty PA, thereby negating the effects of slow variation in PA characteristics such as due to temperature variation.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like reference numbers and designations in the various drawings indicate like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be rearranged. A process may be terminated when its operations are completed but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

What is claimed is:

1. A transmitter, comprising:
circuitry configured to:
receive a source radio frequency (RF) signal in an RF domain;
produce a pre-distortion RF signal in the RF domain with a phase and a magnitude dependent on a phase and a magnitude of the source RF signal;
combine the source RF signal and the pre-distortion RF signal to produce a combined RF signal;
amplify the combined RF signal to produce an amplified RF signal; and
output the amplified RF signal.

2. The transmitter of claim 1, wherein the circuitry is further configured to:
detect one or more second harmonics of an n^{th} instance of the source RF signal from the amplified RF signal; and
adjust the phase and the magnitude of an (n+1)^{th} instance of the pre-distortion RF signal based on the detected one or more second harmonics.

3. The transmitter of claim 1, wherein the source RF signal comprises a plurality of frequency band components, and wherein the circuitry comprises an extremum seeking controller configured to:
obtain from the amplified RF signal, a second order harmonic for each frequency band component of the plurality of frequency band components; and
optimize a cost function defined based on the second order harmonics of the plurality of frequency band components to adjust the phase and the magnitude of the pre-distortion RF signal.

4. The transmitter of claim 3, wherein the cost function is a single-objective function.

5. The transmitter of claim 3, wherein the cost function is an objective function of the ratio of power of the second harmonic component for a frequency band component in the amplified RF signal to power of the source RF signal, and wherein optimization of the cost function comprises minimizing the objective function.

6. The transmitter of claim 1, wherein the source RF signal is a dual tone signal with each tone of the dual tone signal having a different amplitude and a different frequency.

7. The transmitter of claim 1, wherein the circuitry comprises an extremum seeking controller (ESC) configured to:
determine the phase and magnitude of the source RF signal from the amplified RF signal; and
produce the phase and magnitude of the pre-distortion RF signal, based on the phase and magnitude of the source RF signal.

8. The transmitter of claim 7, wherein the ESC comprises:
a high pass filter configured to filter a non-alternating component of the amplified RF signal to produce a filtered output;
a multiplier circuit configured to multiply the filtered output with a sinusoidal input to produce a demodulated signal, wherein the demodulated signal comprises information indicating a gradient of an objective function of the ESC;
an accumulator circuit configured to recursively add the demodulated signal to move one or more parameters of the amplified RF signal in a direction of the gradient of the objective function;
an amplifier configured to add an integrator gain to the demodulated signal in each iteration of the recursive addition to increase convergence of the one or more parameters to reference values; and
a demodulator configured to add the sinusoidal input to an output of the accumulator circuit to create a disturbance in values of settled system parameters.

9. The transmitter of claim 8, further comprising a tuning circuit configured to tune the phase and amplitude of the pre-distortion RF signal, based on an output of the demodulator.

10. The transmitter of claim 9, wherein the tuning circuit adds a frequency and power dependent phase shift to the phase of the pre-distortion RF signal.

11. A signal transmission method, comprising:
receiving a source radio frequency (RF) signal in an RF domain;
producing a pre-distortion RF signal in the RF domain with a phase and a magnitude dependent on a phase and a magnitude of the source RF signal;
combining the source RF signal and the pre-distortion RF signal to produce a combined RF signal;
amplifying the combined RF signal to produce an amplified RF signal; and
outputting the amplified RF signal.

12. The signal transmission method of claim 11, further comprising:
detecting one or more second harmonics of an n^{th} instance of the source RF signal from the amplified RF signal; and
adjusting the phase and the magnitude of an (n+1)^{th} instance of the pre-distortion RF signal based on the detected one or more second harmonics.

13. The signal transmission method of claim 11, wherein the source RF signal comprises a plurality of frequency band components, and wherein the signal transmission method utilizes an extremum seeking controller for:
obtaining from the amplified RF signal, second order harmonics of each frequency band component of the plurality of frequency band components; and
optimizing a cost function defined based on the second order harmonics of the plurality of frequency band components to adjust the phase and the magnitude of the pre-distortion RF signal.

14. The signal transmission method of claim 13, wherein the cost function is a single-objective function.

15. The signal transmission method of claim 13, wherein the cost function is an objective function of the ratio of power of the second harmonic component for a frequency band component in the amplified RF signal to power of the source RF signal, and wherein optimization of the cost function comprises minimizing the objective function.

16. The signal transmission method of claim 11, wherein the source RF signal is a dual tone signal with each tone of the dual tone signal having a different amplitude and a different frequency.

17. The signal transmission method of claim 11, further comprising utilizing an extremum seeking controller (ESC) for:
determining the phase and magnitude of the source RF signal from the amplified RF signal; and
producing the phase and magnitude of the pre-distortion RF signal, based on the phase and magnitude of the source RF signal.

18. The signal transmission method of claim 17, further comprising:
filtering a non-alternating component of the amplified RF signal to produce a filtered output;
multiplying the filtered output with a sinusoidal input to produce a demodulated signal, wherein the demodulated signal comprises information indicating a gradient of an objective function of the ESC;
recursively adding the demodulated signal to move one or more parameters of the amplified RF signal in a direction of the gradient of the objective function;
adding an integrator gain to the demodulated signal in each iteration of the recursive addition to speed up convergence of the system parameters to reference values; and
adding the sinusoidal input to an output of the accumulator circuit to create a disturbance in values of settled system parameters.

19. An extremum seeking controller (ESC) for determining optimum values of amplitude and phase of an injection signal, wherein the injection signal is added as an additional input to a signal transmitter to cancel one or more of harmonics or intermodulation components in an output radio frequency (RF) signal of the signal transmitter, the ESC communicatively coupled with the signal transmitter, the ESC comprising:
an input interface configured to receive the output RF signal of the signal transmitter and an objective function generated from the output RF signal;
a high pass filter configured to filter a non-alternating component of the output RF signal to produce a filtered output;
a multiplier circuit configured to multiply the filtered output with a sinusoidal input to produce a demodulated signal, wherein the demodulated signal comprises information indicating a gradient of the objective function;
an accumulator circuit configured to recursively add the demodulated signal to move one or more parameters of the output RF signal in a direction of the gradient of the objective function;
an amplifier configured to add an integrator gain to the demodulated signal in each iteration of the recursive addition to increase convergence of the one or more parameters to reference values;
a demodulator configured to add the sinusoidal input to an output of the accumulator circuit to create a disturbance in values of settled system parameters; and
an output interface configured to output the optimum values of the amplitude and phase of the injection signal, based on the settled system parameters with the disturbed values.
